(19) United States
(12) Patent Application Publication
(10) Pub. No.: US 2020/0327944 A1
(43) Pub. Date: Oct. 15, 2020

(54) METHOD OF FAST ERASING AN EEPROM WITH LOW-VOLTAGES, WHERE IONS ARE IMPLANTED AT A HIGHER CONCENTRATION TO INCREASE THE INTENSITY OF THE ELECTRIC FIELD BETWEEN THE GATE AND THE SUBSTRATE OR BETWEEN THE GATE AND THE TRANSISTOR AND THUS DECREASE THE REQUIRED VOLTAGE DIFFERENCE FOR ERASING THE EEPROM

(71) Applicant: YIELD MICROELECTRONICS CORP., CHU-PEI CITY (TW)

(72) Inventors: HSIN-CHANG LIN, CHU-PEI CITY (TW); CHENG-YU CHUNG, CHU-PEI CITY (TW); WEN-CHIEN HUANG, CHU-PEI CITY (TW)

(21) Appl. No.: 16/381,193

(22) Filed: Apr. 11, 2019

(51) Int. Cl. G11C 16/14; H01L 29/788; H01L 29/08; H01L 29/423; H01L 29/78; G11C 16/04

(52) U.S. Cl. CPC G11C 16/14; H01L 29/788; G11C 16/0408; H01L 29/42324; H01L 29/7833; H01L 29/0847

(57) ABSTRACT

The present invention discloses a method of fast erasing an EEPROM with low-voltages. The EEPROM includes a transistor structure is formed in a semiconductor substrate and the transistor structure includes a first electric-conduction gate. Same type ions are implanted into a region of the semiconductor substrate, which is near interfaces of a source, a drain and the first electric-conduction gate, or ion-doped regions of the source and the drain, to increase the ion concentration thereof, whereby to reduce the voltage differences required for erasing. Moreover, the source or the drain is floated during erasing to achieve rapid erasing for a large number of memory cells. In addition to the EEPROM with a single gate transistor structure, the present invention also applies to the EEPROM with a single floating gate transistor structure.

### BACKGROUND OF THE INVENTION

### Field of the Invention

The present invention relates to an EEPROM technology, particularly to a method of fast erasing an EEPROM with low-voltages.

### Description of the Related Art

Non-volatile memories, such as Flash memories and EEPROM (Electrically Erasable Programmable Read Only Memory), are semiconductor storage devices that can be electrically written and erased repeatedly. Nowadays, non-volatile memories have been widely used in electronic products because their data will not volatilize after the power source is turned off.

A non-volatile memory is programmable via storing charges to vary the gate voltage of the transistors or via not storing charges to keep the original gate voltage. A non-volatile memory is erasable by removing the charges stored there inside to restore the original gate voltage thereof. The current EEPROM is erased with a higher voltage difference, which causes the memory to have a larger area and a more complicated fabrication process.

In order to overcome the abovementioned problems of the conventional technology, a low-current and low-voltage difference-operated EEPROM is developed and further research is devoted to a fast erasing method with low-voltages for this memory architecture.

### SUMMARY OF THE INVENTION

The primary objective of the present invention is to provide a method of fast erasing an EEPROM with low-voltages, wherein ions are implanted at a higher concentration to increase the intensity of the electric field between the gate and the substrate or between the gate and the transistor and thus decrease the required voltage difference for erasing EEPROM. Meanwhile, the source or the drain is floated for the erasing method to achieve rapid erasing for a large number of memory cells.

To achieve the abovementioned objectives, the present invention proposes a method of fast erasing an EEPROM with low-voltages. The EEPROM comprises a semiconductor substrate, and at least one transistor structure formed in the semiconductor substrate, wherein the transistor structure includes a first dielectric layer formed on the surface of the semiconductor substrate; a first electric-conduction gate formed on the first dielectric layer; and at least two first ion-doped regions formed inside the semiconductor substrate and respectively at two sides of the first electric-conduction gate to separately function as the source and the drain, and wherein the same type of ions are further implanted into the semiconductor substrate (or the first ion-doped region) at the region where the first electric-conduction gate contacts the source and the semiconductor substrate (or the first ion-doped region) at the region where the electric-conduction gate contacts the drain, whereby to decrease the voltage difference required for erasing the EEPROM.

In addition to the abovementioned single-gate transistor structure, the present invention also applies to a floating-gate transistor structure and further comprises a capacitor structure, which is arranged in the surface of the semiconductor substrate and separated from the transistor structure, wherein the capacitor structure includes a second ion-doped region formed inside the semiconductor substrate; a second dielectric layer formed on the surface of the second ion-doped region; and a second electric-conduction gate stacked on the second dielectric layer and electrically connected with the first electric-conduction gate to function as a floating gate.

No matter whether the single-gate transistor structure or the floating-gate transistor structure is used, further implantation of the same type of ions can increase the ion concentration of the semiconductor substrate or the first ion-doped region by 1-10 times.

While the transistor structure of the present invention is an N-type transistor, the first ion-doped region or the second ion-doped region is an N-type doped region, and the semiconductor substrate is a P-type semiconductor substrate or a semiconductor substrate having a P-type well. While the transistor structure of the present invention is a P-type transistor, the first ion-doped region or the second ion-doped region is a P-type doped region, and the semiconductor substrate is an N-type semiconductor substrate or a semiconductor substrate having an N-type well.

No matter whether the single-gate transistor structure or the floating-gate transistor structure is used, different regions of enhanced ion implantation and different transistor structures are respectively corresponding to different operating methods.

While the transistor structure is an N-type transistor and the first ion-doped region is doped with the same type of ions to increase the ion concentration, the erasing method of the present invention comprises a step: respectively applying a gate voltage V_{g}, a source voltage Vₛ, a drain voltage V_{d} and a substrate voltage V_{sub} to the first electric-conduction gate (or the floating gate), the source, the drain and the semiconductor substrate, wherein in erasing, V_{sub}=ground, V_{d}=HV (High Voltage), Vₛ=floating voltage, and V_{g}=0 or <2V, or V_{sub}=ground, V_{d}=floating voltage, Vₛ=HV, and V_{g}=0 or <2V.

While the transistor structure is a P-type transistor and the first ion-doped region is doped with the same type of ions to increase the ion concentration, the operating method of the present invention comprises a step: respectively applying a gate voltage V_{g}, a source voltage Vₛ, a drain voltage V_{d} and a substrate voltage V_{sub} to the first electric-conduction gate (or the floating gate), the source, the drain and the semiconductor substrate, wherein in erasing, V_{sub}=HV, Vₛ=0, V_{d}=floating voltage, and V_{g} is HV or lower than HV within 2V, or V_{sub}=HV, V_{d}=0, Vₛ=floating voltage, and V_{g} is HV or lower than HV within 2V.

No matter whether a P-type transistor or an N-type transistor is used, while the same type of ions are implanted into the semiconductor substrate to increase the ion concentration, the erasing method of the present invention comprises a step: respectively applying a gate voltage V_{g}, a source voltage Vₛ, a drain voltage V_{d} and a substrate voltage V_{sub} to the first electric-conduction gate (or the floating gate), the source, the drain and the semiconductor substrate, wherein for an N-type transistor in erasing, V_{sub}=ground, V_{d}=HV, Vₛ=floating voltage, and V_{g}=0 or <2V, or V_{sub}=ground, Vₛ=HV, V_{d}=floating voltage, and V_{g}=0 or <2V, and wherein for a P-type transistor in erasing, V_{sub}=HV, Vₛ=0, V_{d}=floating voltage, and V_{g} is HV or lower than HV within 2V, V_{sub}=HV, V_{d}=0, Vₛ=floating voltage, and V_{g} is HV or lower than HV within 2V.

Below, embodiments are described in detail in cooperation with the attached drawings to make easily understood the objectives, technical contents, and accomplishments of the present invention.

### BRIEF DESCRIPTION OF THE DRAWINGS

FIG. 1(a) is a diagram schematically showing that additional ions are implanted into first ion-doped regions (the source and the drain) according to one embodiment of the present invention;

FIG. 1(b) is a diagram schematically showing that additional ions are implanted into a semiconductor substrate according to one embodiment of the present invention;

FIG. 2 is a diagram schematically showing a single memory cell with an N-type transistor and a single-gate structure according to one embodiment of the present invention;

FIG. 3 is a diagram schematically showing a single memory cell with an N-type transistor and a single-floating gate structure according to one embodiment of the present invention;

FIG. 4 is a diagram schematically showing a single memory cell with a P-type transistor and a single-gate structure according to one embodiment of the present invention; and

FIG. 5 is a diagram schematically showing a single memory cell with a P-type transistor and a single-floating gate structure according to one embodiment of the present invention.

### DETAILED DESCRIPTION OF THE INVENTION

The present invention proposes a method of fast erasing an EEPROM (Electrically Erasable Programmable Read Only Memory) with low-voltages. The EEPROM of the present invention is characterized in implanting a higher concentration of ions to increase the intensity of the electric field between the gate and the transistor or between the gate and the substrate so as to decrease the voltage difference for erasing. The erasing method of the present invention simultaneously applies operating voltages to the gate, the source and the drain, which are connected with a memory cell, and in the condition of that the source or the drain is floated during erasing to achieve the effects of rapid erasing for a large number of memory cells.

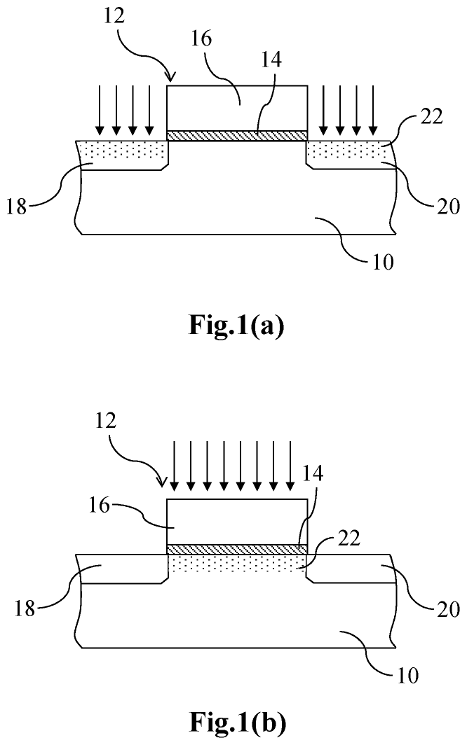

Refer to FIG. 1(a) and FIG. 1(b). The EEPROM of the present invention comprises a semiconductor substrate 10 and at least one transistor structure 12 formed in the semiconductor substrate 10. The transistor structure 12 includes a first dielectric layer 14 formed on the surface of the semiconductor substrate 10; a first electric-conduction gate 16 formed on the first dielectric layer 14; and at least two first ion-doped regions (18 and 20) formed inside the semiconductor substrate 10 and respectively at two sides of the first electric-conduction gate 16 to separately function as a source 18 and a drain 20. The present invention uses the voltage difference between the gate and the source/drain or the voltage difference between the gate and the substrate/well to make electrons pass through the dielectric layer (oxide layer) so as to write or erase EEPROM in a lower current. The present invention uses two methods to increase the concentration of the implanted ions. The first method is shown in FIG. 1(a). In the first method, the same type of ions 22 are further implanted into the regions of the first ion-doped regions 18 and 20, which are respectively at the interface of the source 18 and the first electric-conduction gate 16 and the interface of the drain 20 and the first electric-conduction gate 16. It is meant by the same type of ions 22: if the first ion-doped regions 18 and 20 are P-type, the implanted ions 22 are also P-type; if the first ion-doped regions 18 and 20 are N-type, the implanted ions 22 are also N-type. The ion concentration of the first ion-doped regions 18 and 20 is increased 1-10 times higher than the original ion concentration. Thus, a lower voltage difference can be applied to the transistor structure and the first electric-conduction gate 16 for erasing. The second method is shown in FIG. 1(b). In the second method, the same type of ions 22 are implanted into a region of the semiconductor substrate 10, which is between the interface of the source 18 and the first electric-conduction gate 16 and the interface of the drain 20 and the first electric-conduction gate 16. It is meant by the same type of ions 22: if the semiconductor substrate 10 is P-type, the implanted ions 22 are also P-type; if the semiconductor substrate 10 is N-type, the implanted ions 22 are also N-type. The ion concentration of the semiconductor substrate 10 is increased 1-10 times higher than the original ion concentration. Thus, a lower voltage difference can be applied to the semiconductor substrate 10 and the first electric-conduction gate 16 for erasing.

Spacers (not shown in the drawings) are respectively formed on two side walls of the first dielectric layer 14 and the first electric-conduction gate 16. The implantation of the same type of ions into the first ion-doped regions is undertaken before the formation of the spacers. In one embodiment, each of the first ion-doped regions 18 and 20 further has a light doped drain (LDD). In such a case, LDD is the preferred doped region.

In addition to the abovementioned single-gate structure, the abovementioned two ion concentration-increasing methods are also applied to a single-floating gate structure. The memory cell of the EEPROM with a single-floating gate structure further comprises a capacitor structure. The second electric-conduction gate of the capacitor is electrically connected with the first electric-conduction gate and functions as a single floating gate. The detail of different structures and the operating methods thereof will be described below.

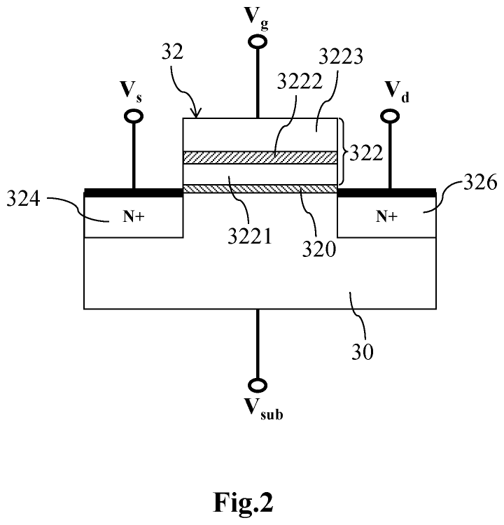

Refer to FIG. 2 a diagram schematically showing a single memory cell with an N-type transistor and a single-gate structure according to one embodiment of the present invention. In the embodiment shown in FIG. 2, a memory cell of the EEPROM of the present invention comprises a P-type semiconductor substrate 30 or a semiconductor substrate with a P-type well. In FIG. 2, the memory cell with a P-type semiconductor substrate 30 is used as an exemplification. An N-type transistor 32, such as an N-type MOSFET (Metal-Oxide-Semiconductor Field-Effect Transistor), is formed in the P-type semiconductor substrate 30. The N-type transistor 32 includes a first dielectric layer 320 formed on the surface of the P-type semiconductor substrate 30; a first electric-conduction gate 322 stacked on the first dielectric layer 320; and two N-type ion-doped regions formed inside the P-type semiconductor substrate 30 and respectively functioning as a source 324 and a drain 326, wherein a channel exists between the source 324 and the drain 326, and wherein first electric-conduction gate 322 further includes a floating gate 3221, a control dielectric layer 3222, a control gate 3223 stacked over the first dielectric layer 320 bottom up in sequence. The structure described above is a single-gate structure.

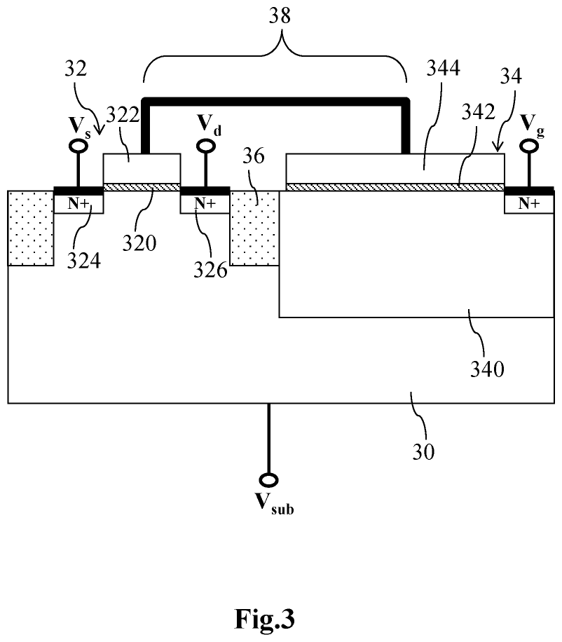

Refer to FIG. 3 a diagram schematically showing a single memory cell with an N-type transistor and a single-floating gate structure according to one embodiment of the present invention. In the embodiment shown in FIG. 3, a memory cell of the EEPROM of the present invention comprises a P-type semiconductor substrate 30, an N-type transistor 32, such as an N-type MOSFET, formed in the P-type semiconductor substrate 30, and an N-well capacitor 34 formed in the P-type semiconductor substrate 30 and separated from the N-type transistor 32 by a spacer 36. The N-type transistor 32 includes a first dielectric layer 320 formed on the surface of the P-type semiconductor substrate 30; a first electric-conduction gate 322 stacked on the first dielectric layer 320; and two N-type ion-doped regions formed inside the P-type semiconductor substrate 30 and respectively functioning as a source 324 and a drain 326, wherein a channel exists between the source 324 and the drain 326. The N-well capacitor 34 includes a second ion-doped region formed in the P-type semiconductor substrate 30 and functioning as an N-type well 340; a second dielectric layer 342 formed on the surface of the N-type well 340; and a second electric-conduction gate 344 formed on the second dielectric layer 342, whereby a top plate-dielectric layer-bottom plate capacitor structure is formed. The first electric-conduction gate 322 of the N-type transistor 32 and the second electric-conduction gate 344 of the N-well capacitor 34 are electrically connected with each other and separated by the spacer 36 to form the structure of a single floating gate 38.

Refer to FIG. 2 and FIG. 3. Suppose that the memory cell of the EEPROM has the N-type transistor 32 and that the same type (N-type) ions are implanted into the regions of the ion-doped regions, which are respectively near the interface of the first electric-conduction gate 322 and the source 324 and the interface of the first electric-conduction gate 322 and the drain 326, to increase the ion concentration by 1-10 times. No matter whether the memory cell structure shown in FIG. 2 or FIG. 3 is used, the erasing method of the present invention comprises a step: respectively applying a gate voltage V_{g}, a source voltage Vₛ, a drain voltage V_{d} and a substrate voltage V_{sub} to the first electric-conduction gate 322 (or the single floating gate 38), the source 324, the drain 326 and the P-type semiconductor substrate 30, wherein in erasing the N-type transistor 32, V_{sub}=ground, V_{d}=HV (High Voltage), Vₛ=floating voltage, and V_{g}=0 or <2V, or V_{sub}=ground, V_{d}=floating voltage, Vₛ=HV, and V_{g}=0 or <2V.

Refer to FIG. 2 and FIG. 3 again. Suppose that the memory cell of the EEPROM has the N-type transistor 32 and that the same type (P-type) ions are implanted into the region of the P-type semiconductor substrate 20, which is near the interface of the source 324 and the first electric-conduction gate 322 and the interface of the drain 326 and the first electric-conduction gate 322, to increase the ion concentration by 1-10 times. The erasing method of the present invention comprises a step: respectively applying a gate voltage V_{g}, a source voltage Vₛ, a drain voltage V_{d} and a substrate voltage V_{sub} to the first electric-conduction gate 322 (or the single floating gate 38), the source 324, the drain 326 and the semiconductor substrate 30, wherein in erasing the N-type transistor, V_{sub}=ground, V_{d}=HV, Vₛ=floating voltage, and V_{g}=0 or <2V, or V_{sub}=ground, Vₛ=HV, V_{d}=floating voltage, and V_{g}=0 or <2V.

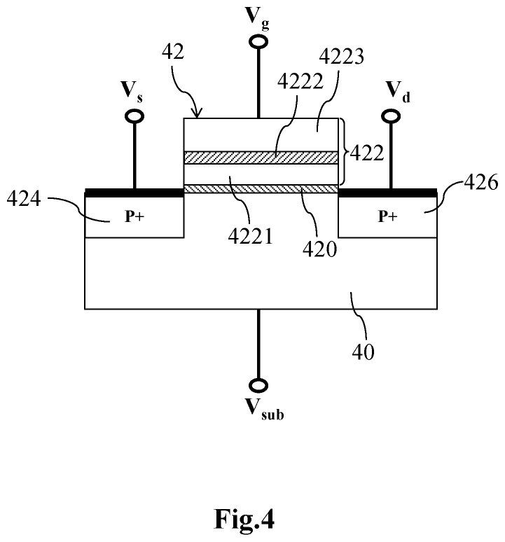

Refer to FIG. 4 a diagram schematically showing a single memory cell with a P-type transistor and a single-gate structure according to one embodiment of the present invention. In the embodiment shown in FIG. 4, a memory cell of the EEPROM of the present invention comprises an N-type semiconductor substrate 40 or a semiconductor substrate with an N-type well. In FIG. 4, the memory cell with an N-type semiconductor substrate 40 is used as an exemplification. A P-type transistor 42, such as a P-type MOSFET, is formed in the N-type semiconductor substrate 40. The P-type transistor 42 includes a first dielectric layer 420 formed on the surface of the N-type semiconductor substrate 40; a first electric-conduction gate 422 stacked on the first dielectric layer 420; and two P-type ion-doped regions formed inside the N-type semiconductor substrate 40 and respectively functioning as a source 424 and a drain 426, wherein a channel exists between the source 424 and the drain 426, and wherein first electric-conduction gate 422 further includes a floating gate 4221, a control dielectric layer 4222, a control gate 4223 stacked over the first dielectric layer 420 bottom up in sequence. The structure described above is a single-gate structure.

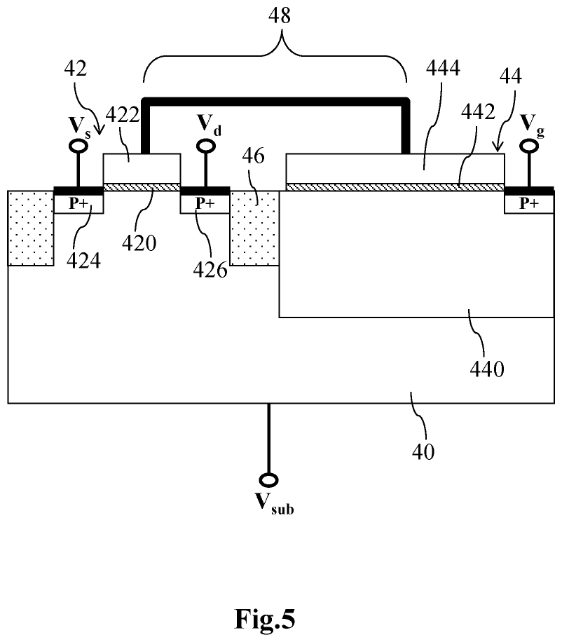

Refer to FIG. 5 a diagram schematically showing a single memory cell with a P-type transistor and a single-floating gate structure according to one embodiment of the present invention. In the embodiment shown in FIG. 5, a memory cell of the EEPROM of the present invention comprises an N-type semiconductor substrate 40. A P-type transistor 42 and a P-well capacitor 44 are formed in the N-type semiconductor substrate 40 and separated by a spacer 46. The P-type transistor 42, such as a P-type MOSFET, includes a first dielectric layer 420 formed on the surface of the N-type semiconductor substrate 40; a first electric-conduction gate 422 stacked on the first dielectric layer 420; and two P-type ion-doped regions formed inside the N-type semiconductor substrate 40 and respectively functioning as a source 424 and a drain 426, wherein a channel exists between the source 424 and the drain 426. The P-well capacitor 44 includes a second ion-doped region formed inside the N-type semiconductor substrate 40 and functioning as a P-type well 440, a second dielectric layer 442 formed on the surface of the P-type well 440, and a second electric-conduction gate 444 formed on the second dielectric layer 442, whereby to form a top plate-dielectric layer-bottom plate capacitor structure. The first electric-conduction gate 422 of the P-type transistor 42 and the second electric-conduction gate 444 of the P-well capacitor 44 are electrically connected with each other and separated by the spacer 46 to form a single floating gate 48.

Refer to FIG. 4 and FIG. 5. No matter whether the memory cell is that shown in FIG. 4 or FIG. 5, it has a P-type transistor 42, and the same type (P-type) ions are implanted into the ion-doped regions near the interface of the source 424 and the first electric-conduction gate 422 and the interface of the drain 426 and the first electric-conduction gate 422 to increase the ion concentration by 1-10 times. In such cases, the erasing method of the present invention comprises a step: respectively applying a gate voltage V_{g}, a source voltage Vₛ, a drain voltage V_{d} and a substrate voltage V_{sub} to the first electric-conduction gate 422 (or the single floating gate 48), the source 424, the drain 426 and the semiconductor substrate 40, wherein in erasing the P-type transistor, V_{sub}=HV, Vₛ=0, V_{d}=floating voltage, and V_{g} is HV or lower than HV within 2V, or V_{sub}=HV, V_{d}=0, Vₛ=floating voltage, and V_{g} is HV or lower than HV within 2V.

Refer to FIG. 4 and FIG. 5 again. No matter whether the memory cell is that shown in FIG. 4 or FIG. 5, it has a P-type transistor 42, and the same type (N-type) ions are implanted into the region of the N-type semiconductor substrate 40, which is near the interface of the source 424 and the first electric-conduction gate 422 and the interface of the drain 426 and the first electric-conduction gate 422 to increase the ion concentration by 1-10 times. In such cases, the erasing method of the present invention comprises a step: respectively applying a gate voltage V_{g}, a source voltage Vₛ, a drain voltage V_{d} and a substrate voltage V_{sub} to the first electric-conduction gate 422 (or the single floating gate 48), the source 424, the drain 426 and the semiconductor substrate 40, wherein in erasing, V_{sub}=HV, Vₛ=0, V_{d}=floating voltage, and V_{g} is HV or less than 2V below HV, or V_{sub}=HV, V_{d}=0, Vₛ=floating voltage, and V_{g} is HV or lower than HV within 2V.

In the EEPROM according to the present invention, the erasing correlates with the doping concentration, which influences the voltages-needed applying to the source, the drain and the gate. As long as sufficient voltage differences are applied to the source, the drain and the gate, the erasing will be enabled. Therefore, the high voltage required in the conventional technology can be reduced via replacing the grounding with a negative voltage. For such a memory architecture that low-voltage operations can be realized, the present invention particularly proposes that the source or the drain can be set to a floating condition during erasing, so that the erasing operation of the memory cell is simpler and faster.

The embodiments have been described above to demonstrate the technical thoughts and characteristics of the present invention and enable the persons skilled in the art to understand, make, and use the present invention. However, these embodiments are only to exemplify the present invention but not to limit the scope of the present invention. Any equivalent modification or variation according to the spirit of the present invention is to be also included within the scope of the present invention.

1. A method of fast erasing an electrically erasable programmable read only memory (EEPROM) with low-voltages, wherein said electrically erasable programmable read only memory comprises a semiconductor substrate and at least one N-type transistor structure formed in said semiconductor substrate, and wherein said N-type transistor structure includes a first electric-conduction gate and at least two first ion-doped regions formed inside said semiconductor substrate and located at two sides of said first electric-conduction gate to function as a source and a drain, and wherein regions of said first ion-doped regions, which are near an interface of said source and said first electric-conduction gate and an interface of said drain and said first electric-conduction gate, are further implanted with the same type of ions to increase an ion concentration of said regions of said first ion-doped regions, and wherein said method comprises a step:
respectively applying a gate voltage V_{g}, a source voltage Vₛ, a drain voltage V_{d} and a substrate voltage V_{sub} to said first electric-conduction gate, said source, said drain and said semiconductor substrate, and said voltages meet the following conditions:
wherein in erasing,
V_{sub}=ground, V_{d}=HV (High Voltage), Vₛ=floating voltage, and V_{g}=0 or <2V, or V_{sub}=ground, Vₛ=HV, V_{d}=floating voltage, and V_{g}=0 or <2V, wherein a voltage difference between the source voltage Vₛ and the drain voltage V_{d} increases a difference between energy bands of the source and the drain based on the first ion-doped regions with increased ion concentration.

2. The method of fast erasing an EEPROM with low-voltages according to claim 1, wherein said electrically erasable programmable read only memory further comprises a capacitor structure formed in said semiconductor substrate and separated from said at least one N-type transistor structure, and wherein said capacitor structure includes a second ion-doped region formed inside said semiconductor substrate and a second electric-conduction gate, and wherein said second electric-conduction gate is electrically connected with said first electric-conduction gate to function as a single floating gate, and wherein said gate voltage Vg is applied to said single floating gate.

3. The method of fast erasing an EEPROM with low-voltages according to claim 1, wherein said same type of ions are implanted into said semiconductor substrate or said first ion-doped regions to increase an ion concentration of said semiconductor substrate or said first ion-doped regions by 1-10 times.

4. The method of fast erasing an EEPROM with low-voltages according to claim 1, wherein said N-type transistor structure is an N-type metal-oxide-semiconductor field-effect transistor (MOSFET).

5. The method of fast erasing an EEPROM with low-voltages according to claim 1, wherein a lightly-doped drain (LDD) is formed in said first ion-doped region.

6. A method of fast erasing an electrically erasable programmable read only memory (EEPROM) with low-voltages, wherein said electrically erasable programmable read only memory comprises a semiconductor substrate and at least one P-type transistor structure formed in said semiconductor substrate, and wherein said P-type transistor structure includes a first electric-conduction gate and at least two first ion-doped regions formed inside said semiconductor substrate and located at two sides of said first electric-conduction gate to function as a source and a drain, and wherein regions of said first ion-doped regions, which are near an interface of said source and said first electric-conduction gate and an interface of said drain and said first electric-conduction gate, are further implanted with the same type of ions to increase an ion concentration of said regions of said first ion-doped regions, and wherein said method comprises a step:
respectively applying a gate voltage V_{g}, a source voltage Vₛ, a drain voltage V_{d} and a substrate voltage V_{sub} to said first electric-conduction gate, said source, said drain and said semiconductor substrate, and said voltages meet the following conditions:
wherein in erasing,
V_{sub}=HV, Vₛ=0, V_{d}=floating voltage, and V_{g} is HV or lower than HV within 2V, or V_{sub}=HV, V_{d}=0, Vₛ=floating voltage, and V_{g} is HV or lower than HV within 2V, wherein a voltage difference between the source voltage Vₛ and the drain voltage V_{d} increases a difference between energy bands of the source and the drain based on the first ion-doped regions with increased ion concentration.

7. The method of fast erasing an EEPROM with low-voltages according to claim 6, wherein said electrically erasable programmable read only memory further comprises a capacitor structure formed in said semiconductor substrate and separated from said at least one P-type transistor structure, and wherein said capacitor structure includes a second ion-doped region formed inside said semiconductor substrate and a second electric-conduction gate, and wherein said second electric-conduction gate is electrically connected with said first electric-conduction gate to function as a single floating gate, and wherein said gate voltage Vg is applied to said single floating gate.

8. The method of fast erasing an EEPROM with low-voltages according to claim 6, wherein said same type of ions are implanted into said semiconductor substrate or said first ion-doped regions to increase an ion concentration of said semiconductor substrate or said first ion-doped regions by 1-10 times.

9. The method of fast erasing an EEPROM with low-voltages according to claim 6, wherein said P-type transistor structure is a P-type metal-oxide-semiconductor field-effect transistor (MOSFET).

10. The method of fast erasing an EEPROM with low-voltages according to claim 6, wherein a lightly-doped drain (LDD) is formed in said first ion-doped region.

11. A method of fast erasing an electrically erasable programmable read only memory (EEPROM) with low-voltages, wherein said electrically erasable programmable read only memory comprises a semiconductor substrate and at least one transistor structure formed in said semiconductor substrate, and wherein said transistor structure includes a first electric-conduction gate and at least two first ion-doped regions formed inside said semiconductor substrate and located at two sides of said first electric-conduction gate to function as a source and a drain, and wherein regions of said first ion-doped regions, which are near an interface of said source and said first electric-conduction gate and an interface of said drain and said first electric-conduction gate, are further implanted with the same type of ions to increase an ion concentration of said regions of said first ion-doped regions, and wherein said erasing method comprises a step:
respectively applying a gate voltage V_{g}, a source voltage Vₛ, a drain voltage V_{d} and a substrate voltage V_{sub} to said first electric-conduction gate, said source, said drain and said semiconductor substrate, and said voltages meet the following conditions:
wherein while said transistor structure is an N-type transistor structure,
in erasing,
V_{sub}=ground, V_{d}=HV (High Voltage), Vₛ=floating voltage, and V_{g}=0 or <2V, or V_{sub}=ground, Vₛ=HV, V_{d}=floating voltage, and V_{g}=0 or <2V, wherein a voltage difference between the source voltage Vₛ and the drain voltage V_{d} increases a difference between energy bands of the source and the drain based on the first ion-doped regions with increased ion concentration, and
wherein while said transistor structure is a P-type transistor structure,
in erasing,
V_{sub}=HV, Vₛ=0, V_{d}=floating voltage, and V_{g} is HV or lower than HV within 2V, or V_{sub}=HV, V_{d}=0, Vₛ=floating voltage, and V_{g} is HV or lower than HV within 2V, wherein a voltage difference between the source voltage Vₛ and the drain voltage V_{d} increases a difference between energy bands of the source and the drain based on the first ion-doped regions with increased ion concentration.

12. The method of fast erasing an EEPROM with low-voltages according to claim 11, wherein said electrically erasable programmable read only memory further comprises a capacitor structure formed in said semiconductor substrate and separated from said at least one transistor structure, and wherein said capacitor structure includes a second ion-doped region formed inside said semiconductor substrate and a second electric-conduction gate, and wherein said second electric-conduction gate is electrically connected with said first electric-conduction gate to function as a single floating gate, and wherein said gate voltage Vg is applied to said single floating gate.

13. The method of fast erasing an EEPROM with low-voltages according to claim 12, wherein while said transistor structure is an N-type transistor, said first ion-doped regions are N-type ion-doped regions, and said semiconductor substrate is a P-type semiconductor substrate or a semiconductor substrate with a P-type well, and wherein while said transistor structure is a P-type transistor, said first ion-doped regions are P-type ion-doped regions, and said semiconductor substrate is an N-type semiconductor substrate or a semiconductor substrate with an N-type well.

14. The method of fast erasing an EEPROM with low-voltages according to claim 11, wherein while said transistor structure is an N-type transistor, said first ion-doped regions and said second ion-doped region are N-type ion-doped regions, and said semiconductor substrate is a P-type semiconductor substrate or a semiconductor substrate with a P-type well, and wherein while said transistor structure is a P-type transistor, said first ion-doped regions and said second ion-doped region are P-type ion-doped regions, and said semiconductor substrate is an N-type semiconductor substrate or a semiconductor substrate with an N-type well.

15. The method of fast erasing an EEPROM with low-voltages according to claim 11, wherein said same type of ions are implanted into said semiconductor substrate or said first ion-doped regions to increase an ion concentration of said semiconductor substrate or said first ion-doped regions by 1-10 times.

16. The method of fast erasing an EEPROM with low-voltages according to claim 11, wherein said transistor structure is a metal-oxide-semiconductor field-effect transistor (MOSFET).

17. The method of fast erasing an EEPROM with low-voltages according to claim 11, wherein a lightly-doped drain (LDD) is formed in said first ion-doped region.
